(19) United States
(12) Patent Application Publication
(10) Pub. No.: US 2023/0187229 A1
(43) Pub. Date: Jun. 15, 2023

(54) CERAMIC ADDITIVE MANUFACTURING TECHNIQUES FOR GAS INJECTORS

(71) Applicant: Lam Research Corporation, Fremont, CA (US)

(72) Inventors: Pankaj Jyoti Hazarika, Sherwood, OR (US); Seyedalireza Torbatisarraf, San Jose, CA (US)

(21) Appl. No.: 17/912,358

(22) PCT Filed: Mar. 29, 2021
(86) PCT No.: PCT/US2021/024744

§ 371 Date: Sep. 16, 2022

Related U.S. Application Data
(60) Provisional application No. 63/005,874, filed on Apr. 6, 2020.

(51) Int. Cl. H01L 21/67; B33Y 80/00; B28B 1/00; B33Y 10/00; C04B 35/638; C04B 35/64

(52) U.S. Cl. CPC H01L 21/67017; B33Y 80/00; B28B 1/001; B33Y 10/00; C04B 35/638; C04B 35/64; C04B 2235/6026; H01J 37/3244

(57) ABSTRACT

A ceramic gas injector and method of fabrication are described. The gas injector has an inlet portion to which a gas is introduced via an inlet hole and contains a conformal channel between the inlet hole and a sidewall, an outlet portion from which the gas is provided from the gas injector and a collar disposed between the inlet and outlet portions. The channel extends into the collar. The channel has channel sections each of which extends through the inlet portion and terminates at both inlet ends before reaching the inlet face and collar ends before reaching the outlet portion. Alternating adjacent pairs of channel sections are connected via the inlet ends with adjacent pairs that are not connected via the inlet ends connected via the collar ends. Ports in a sidewall of the collar are connected with an adjacent pairs of sections not connected via the inlet ends.

### CLAIM OF PRIORITY

This application claims the benefit of priority to U.S. Patent Application Ser. No. 63/005,874, filed on Apr. 6, 2020, which is incorporated by reference herein in its entirety.

### TECHNICAL FIELD

The present disclosure generally relates to additive manufacturing. Some embodiments relate to additive manufacturing (AM) for a ceramic part. Some specific embodiments relate to AM for a ceramic gas injector.

### BACKGROUND

Semiconductor device fabrication is a continually increasingly complicated and involved set of processes, involving a large number of deposition, etching and removal steps to improve device performance and increase device density in integrated circuits (ICs). For example, the smallest device feature size has shrunk from microns to about 22 nm. To achieve a reduction in feature size, in each IC generation new fabrication processes and equipment are designed, as well as considerable time spent altering device and circuit layout. As successive generations of ICs and processes have become more complicated, the equipment used to fabricate the ICs has correspondingly become more complex and exacting.

One such piece of equipment within the fabrication chamber is the gas injector, through which various gasses may be introduced for the disparate fabrication processes. One issue with current gas injectors is that such gas injectors are formed from bulk ceramics (e.g., Alumina, Yttria) and fabricated using a machining method that causes depth of damage (damage with a penetration depth) in the ceramic material that forms an injector. In particular, many ceramic components are finished by grinding, which often causes damage to the machined components. The depth of damage (DoD) introduced by grinding is caused by pulverization and microcracking of the ceramic and related to the material properties (e.g., brittleness) of the ceramic, as well as the grinding techniques used during the machining. Depth of damage is, moreover, not isolated only to ceramics, it is also a known problem in other chamber materials such as quartz, Si, and SiC. Control of, or reduction in, depth of damage is, at a minimum, challenging using conventional methodologies. The machining thus induces chips and cracks around injector ports, which may contribute to wafer defects during plasma exposure, as well as limiting the ability to design parts to account for design manufacturability challenges. Beyond this challenge, as the bulk material is changed, extensive tuning may be used to determine machining parameters and fabrication methodology to optimize for the new material properties. For example, Alumina is a harder and tougher material than Yttria, which makes it easier to machine and control surface morphology and damage than Yttria.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure. The information described in this section is thus provided to offer the skilled artisan a context for the following disclosed subject matter and should not be considered as admitted prior art.

### SUMMARY

Some embodiments describe a gas injector that comprises an inlet portion including an inlet hole on an inlet face of the inlet portion. The inlet portion receives a processing gas introduced via the inlet hole during semiconductor processing and further includes a conformal channel disposed between the inlet hole and a sidewall of the inlet portion. The gas injector also comprises an outlet portion connected to the inlet hole and that includes an outlet hole from which the processing gas is provided from the gas injector during the semiconductor processing. In addition, a collar is disposed between the inlet portion and the outlet portion. The collar has a larger diameter than the inlet portion and the outlet portion, the conformal channel extending into the collar.

In some embodiments, the conformal channel has a plurality of channel sections each of which extends through the inlet portion and terminates at inlet channel ends before reaching the inlet face.

In some embodiments, each channel section also terminates at collar channel ends before reaching the outlet portion.

In some embodiments, alternating adjacent pairs of channel sections are connected via the inlet channel ends such that each inlet channel end is separated from an adjacent inlet channel end, and at least some of adjacent pairs of channel sections not connected via the inlet channel ends are connected via the collar channel ends.

In some embodiments, the collar further comprises a sidewall having ports connected with at least one of the adjacent pairs of channel sections not connected via the inlet channel ends.

In some embodiments, the conformal channel is a single channel that extends around substantially an entirety of the inlet hole.

In some embodiments, at least one of the inlet channel ends or the collar channel ends of each channel section have an arcuate shape.

In some embodiments, the inlet hole comprises a single inlet central bore and a plurality of secondary inlet holes surrounding the inlet central bore. In this case, the secondary inlet holes are equidistant from a center of the inlet central bore and each secondary inlet hole is equiangular from each adjacent secondary inlet hole. In addition, the outlet hole comprises a single outlet central bore connected with the inlet central bore and a plurality of secondary outlet holes connected with the secondary inlet holes. In this case, the secondary outlet holes are disposed on a sidewall of the outlet portion. Also, an arc of one of each inlet channel end or each collar channel end is centered angularly around a different secondary inlet hole.

In some embodiments, an arc of at least another of each inlet channel end or each collar channel end is centered angularly between adjacent secondary inlet holes.

In some embodiments, each channel section has a diameter smaller than a diameter of each secondary inlet hole.

In some embodiments, the gas injector further includes a connector integrally formed with the sidewall of the inlet portion, the connector sized to be connected to a gas manifold configured to supply the gas to the gas injector, the gas injector formed from a ceramic material.

In some embodiments, the conformal channel is disposed such that at least one dimension of material of the gas injector surrounding the conformal channel is limited to less than about 6 mm.

In some embodiments, a depth of damage of the gas injector is less than about 1 micron.

In a method of fabricating a ceramic gas injector, the method includes printing, using AM equipment, a green part corresponding to the gas injector. The green part is formed from a ceramic powder and binder and has an inlet portion comprising a central bore and a conformal channel in a sidewall. The conformal channel terminates before reaching a top face. The green part also has a collar disposed between the inlet portion and an outlet portion. The conformal channel extends into the collar and terminates before extending into the outlet portion. The conformal channel is disposed such that at least one dimension of material of the gas injector surrounding the conformal channel is limited to less than about 6 mm. The method further includes debinding the green part to remove the binder; and sintering the green part after the debinding to form the gas injector, the gas injector having a depth of damage less than about 1 micron.

In some embodiments, printing the green part further includes printing the conformal channel to have a plurality of channel sections each of which extends through the inlet portion and terminates at inlet channel ends before reaching the top face. Alternating adjacent pails of channel sections are connected via the inlet channel ends such that each inlet channel end is separated from an adjacent inlet channel end, and all but one adjacent pair of channel sections not connected via the inlet channel ends being connected via the collar channel ends. The collar is printed to have ports in a sidewall and that are connected with the one adjacent pair of channel sections not connected via the inlet channel ends.

In some embodiments, the central bore is encircled by secondary inlet holes, and printing the green part further includes printing the inlet channel ends and the collar channel ends such that an arc of one of each inlet channel end or each collar channel end is centered angularly' around a different secondary inlet hole and an arc of at least another of each inlet channel end or each collar channel end is centered angularly between adjacent secondary inlet holes.

In some embodiments, a semiconductor processing system has a gas manifold configured to supply gasses used during semiconductor processing, a gas injector and a processing chamber within which a semiconductor wafer is disposed. The gas injector has an inlet portion to which the gasses are to be introduced via an inlet hole on an inlet face of the inlet portion, an outlet portion from which the gasses are provided from the gas injector via an outlet hole connected to the inlet hole, and a collar disposed between the inlet portion and the outlet portion. The inlet portion is coupled with the gas manifold and. The inlet portion has a conformal channel disposed between the inlet hole and a sidewall of the inlet portion. The inlet hole has a single inlet central bore and a plurality of secondary inlet holes surrounding the inlet central bore. The secondary inlet holes are equidistant from a center of the inlet central bore. Each secondary inlet hole is equiangular from each adjacent secondary inlet hole. The outlet hole has a single outlet central bore connected with the inlet central bore and a plurality of secondary outlet holes connected with the secondary inlet holes. The secondary outlet holes are disposed on a sidewall of the outlet portion. The collar has a larger diameter than the inlet portion and the outlet portion. The conformal channel extends into the collar. The gas injector is coupled to the processing chamber such that the gasses are provided into the processing chamber from the outlet portion.

In some embodiments, the conformal channel has a plurality of channel sections each of which extends through the inlet portion, terminates at inlet channel ends before reaching the inlet face, and also terminates at collar channel ends before reaching the outlet portion.

In some embodiments, alternating adjacent pairs of channel sections are connected via the inlet channel ends such that each inlet channel end is separated from an adjacent inlet charnel end, at least some of adjacent pairs of channel sections not connected via the inlet channel ends are connected via the collar channel ends, and the collar further has a sidewall having ports connected with at least one of the adjacent pairs of channel sections not connected via the inlet channel ends.

In some embodiments, a connector is integrally formed with the sidewall of the inlet portion, the connector sized to be connected to the gas manifold.

### BRIEF DESCRIPTION OF THE DRAWINGS

Some embodiments are illustrated by way of example and not limitation in the views of the accompanying drawings. Corresponding reference characters indicate corresponding parts throughout the several views. Elements in the drawings are not necessarily drawn to scale. The configurations shown in the drawings are merely examples and should not be construed as limiting the scope of the disclosed subject matter in any manner.

FIG. 1 shows laser stereolithography, according to an example embodiment.

FIG. 2 shows vat photopolymerization, according to another example embodiment.

FIG. 3 shows a 3D material jetting apparatus, according to another example embodiment.

FIG. 4 shows a flowchart of AM, according to an example embodiment.

FIG. 5A shows a bottom perspective view of the gas injector, according to an example embodiment.

FIG. 5B shows a top perspective view of the gas injector of FIG. 5A.

FIG. 5C shows a cross-sectional view of the gas injector of FIGS. 5A-5B.

FIG. 5D shows an enlarged view of a bottom of the gas injector of FIGS. 5A-5C.

FIG. 5E shows a cross-sectional view of the gas injector of FIGS. 5A-5D along line B-B′ shown in FIG. 5C.

FIG. 5F shows a cross-sectional view of the gas injector of FIGS. 5A-5E along line C-C′ shown in FIG. 5C.

FIG. 5G shows a cross-sectional view of a portion of the bottom of the gas injector of FIGS. 5A-5F

FIG. 5H shows a side view of the portion of the gas injector of FIGS. 5A-5G.

FIG. 5I shows a bottom view of the gas injector of FIGS. 5A-5H.

FIG. 6 shows a perspective of a gas injector according to another embodiment.

FIG. 7 is a diagram of a machine associated with AM of a component, according to an example embodiment.

FIGS. 8A-8F show cross-sections of different regions of an injector fabricated by subtractive manufacturing and an injector fabricated by AM, according to an example embodiment.

FIGS. 9A-9H show surface morphology of an inlet hole of an injector fabricated by subtractive manufacturing and an injector fabricated by AM, according to an example embodiment.

FIGS. 10A-10D show grain sizes an injector fabricated by subtractive manufacturing and fabricated by AM, according to an example embodiment.

### DESCRIPTION

The description that follows includes systems, methods, techniques, instruction sequences, and computing machine program products that embody illustrative embodiments of the present disclosure. In the following description, for purposes of explanation, numerous specific details are set forth in order to provide a thorough understanding of example embodiments. It will be evident, however, to one skilled in the art, that the present inventive subject matter may be practiced without these specific details.

Rather than use a subtractive manufacturing technique in which the component is machined from a solid block of material (including cutting, drilling, and grinding away unwanted excess material from the solid block of material, such as metal or ceramic), an AM technology may be used to print the component which, in one embodiment, may be a ceramic gas injector. The ceramics may include oxides such as silicon-based oxides, aluminium-based oxides, magnesium-based oxides, zirconium-based oxides, strontium-based oxides, and titanium-based oxides among others, non-oxides such as silicon carbide, silicon nitride, zirconium carbide, aluminum nitride and boron nitride, and oxycarbides or oxynitrides. In general, AM is the process of creating an object by building the object layer by layer of material rather than by removal of material. AM may also be called additive fabrication, additive processing, or additive layer manufacturing, in addition to layer-wise manufacturing, 3D printing and freeform fabrication. Although AM typically refers to 3D printing, the term can refer to any process where a product is created by building an object from a material rather than removing material from a block of the designated material by milling or machining, for example to form the object.

When AM is used machining may be avoided, leading to a reduced depth of damage. In some cases, the depth of damage for AM objects may be almost zero. In addition, objects created by AM may include a smoother surface morphology, including all internal areas, compared to machined surfaces. The AM component may be cleaner than a similar machined component. Moreover, the grain size of the material used to form the ceramic component may be an order of magnitude smaller compared to conventional materials, which may provide more uniformity on overall performance of the object. As the powder used to create the component may have a submicron range grain size, tighter control of the overall grain size may result in correspondingly tight control of the AM process and final component quality. When designing new generations of injectors, the use of AM may result in a faster development cycle time and the use of new or different material(s) with same performance outcome once the raw powder is optimized for printing. As such, the AM process may be portable between various materials with less process tuning used while switching material. In addition, the amount of material wasted during AM may enable the use of more advanced ceramics at an equivalent price of injectors made with current subtractive manufacturing processes.

In a 3D additive manufacturing process, a design for fabrication of an object may be initially created using, e.g., computer aided design (CAD) or software. Other software may then translate the design into instructions for creation using a layer-by-layer AM framework. These instructions are sent to the AM device (e.g., 3D printer) to create the object using the materials supplied to the AM device.

In some embodiments, following the instructions, a nozzle may extrude material or such material may be otherwise drawn through a heated nozzle mounted on a movable ann. The arm moves horizontally, rastering successive layers on top of each other, while a bed on which the object being built moves vertically. Each layer has a composition determined by the supplied material. As each layer is dependent on the materials provided to the 3D printer, which may be changed from layer-to-layer, the formulation of each layer may be independent of each other layer (and thus may be the same as, or different from, another layer). Each successive layer bonds to the preceding layer of melted or partially incited material using precise temperature control to control the amount of melting or bonding between the layers may occur using chemical bonding agents. The layer-by-layer building continues until the instructions are completed and the final object is obtained. The materials used include not only ceramics, but also metal powder, thermoplastics, composites, glass and even edible materials like chocolate. In some embodiments, directed energy deposition may be used to melt the material from the nozzle, rather than melting the layer using direct thermal energy to the nozzle, a movable electron beam gun, or laser.

In other embodiments, thermal activation of powders may be used by powder bed fusion. In particular, a bed that is filled with a desired material may be selectively heated to melt or sinter the powder and form a solid object layer by layer. The selective heating may be performed using lasers or electron beams. Alternatively, rather than selective heating, a polymer may be used to adhere portions of powder together, and the structure placed in a furnace where the powder is sintered at a high enough temperature to melt the grains together and remove all other materials present, as described in more detail below.

Other embodiments may employ vat photopolymerization to form the object. Although various AM processes the techniques above may be used to create a component such as a ceramic injector, the use of vat photopolymerization may be desirable due to the maturity of the vat photopolymerization technology, wide variety of available materials and high accuracy and precision when the vat photopolymerization is used.

One object that may be created by AM is a gas injector used during semiconductor processing (e.g., during etching of one or more of the layers used to build the semiconductor device on the semiconductor wafer). Such a gas injector may have multiple gas holes and a honeycomb structure, as described in more detail below. This structure is challenging to manufacture as the edges of the holes are prone to chipping, and layers within the holes may be rough and may interact badly with acid used for etching.

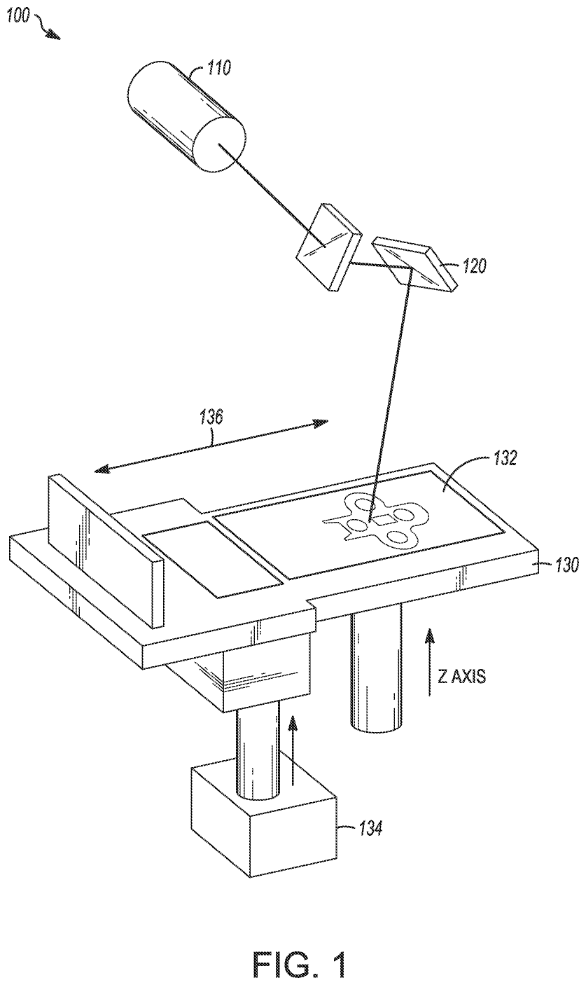

FIG. 1 shows laser based stereolithography, according to an example embodiment. Although some elements are shown in FIG. 1, additional elements may be present in other embodiments. The apparatus 100 uses a stereo lithography-based process that employs a rastening laser 110. More specifically, as shown in FIG. 1, the apparatus 100 includes a laser 110 positioned over a bed or vat 130 filled with liquid resin photopolymer. The laser 110 may typically emit higher-energy photons, and thus emit ultraviolet (UV) radiation. The UV radiation may be guided by mirrors 120 in a single (x or y) direction or around a plane (x and y directions). In some embodiments, the UV laser 110 may be mechanically movable instead of, or in addition to, being moved by the mirrors 120. The movement of the mirrors 120 and/or UV laser 110 may be controlled electronically based on the instructions to create the object. The vat 130 may be movable in a direction perpendicular to the plane (i.e., as shown, the z direction). Although not shown in FIG. 1, in some embodiments, optics (e.g., lens) may be disposed between UV laser 110 and the mirrors 120 and/or between the mirrors 120 and the vat 130.

The radiation from the UV laser 110 is directed towards the working surface 132 of the vat 130 to form individual resin layers from the photopolymer in the vat 130 as the radiation from the UV laser 110 moves around the working surface 132. In particular, a blade 136 may be used to introduce or spread a tine layer of the photopolymer across the working surface 132. The fine layer of photopolymer in the vat 130 is cured into a layer using photopolymerization of the photopolymer on the working surface 132 based on the instructions. The fine layer of the photopolymer may thus be provided after the last layer has been hardened by application of the radiation from the UV laser 110. The photopolymer in the vat 130 is supplied from a paste tank 134 via the blade 136.

The technique shown in FIG. 1 thus may print the object from the bottom up. Although only one laser 110 is shown, in other embodiments, multiple lasers 110 may be used to create objects more rapidly, using a larger vat 130 than that able to be provided for an embodiment in which a single laser 110 is used. A multi-laser embodiment may also permit larger objects to be created with high precision or reduce costs by nesting multiple objects.

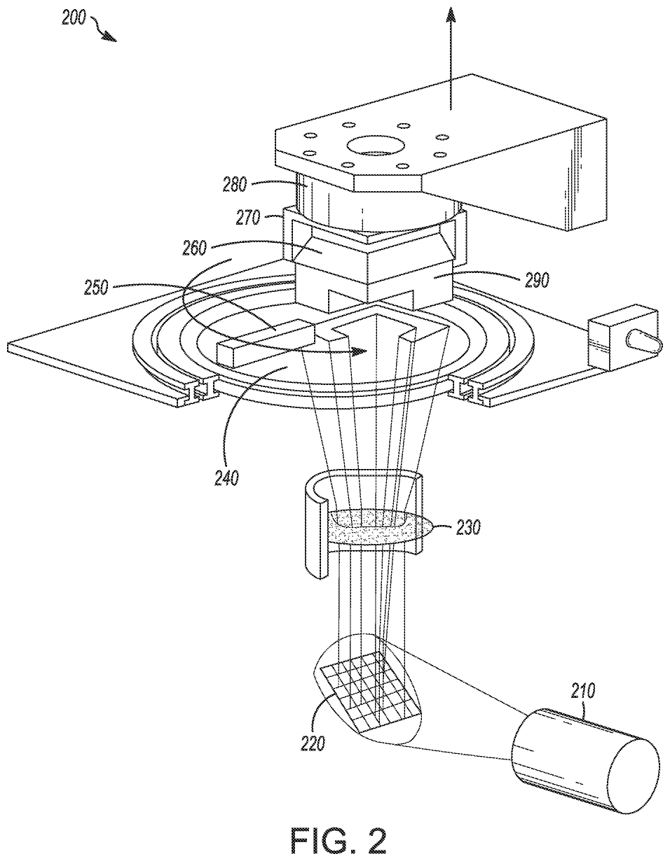

FIG. 2 shows vat photopolymerization, according to another example embodiment. As in FIG. 1, although some elements are shown in FIG. 2, additional elements may be present in other embodiments. The apparatus 200 uses a light projector through known digital light processing (DLP) techniques 210 to cure the photopolymer rather than rastering a laser 110. That is, rather than sweeping the laser beam, digital light processing is used to create the object. More specifically, as shown in FIG. 2, light (e.g., UV radiation) from the light projector 210 impinges on a digital micromirror device (DMD) 220, or dynamic mask. The DMD 220 is adjusted based on the instructions for the particular layer being formed to reflect specific portions of the UV radiation toward the photopolymer in the vat 240.

Unlike the technique shown in FIG. 1, in FIG. 2 the UV radiation impinges on the vat 240 from the bottom. Thus, the object may be printed layer by layer from the bottom (i.e., upside down). As shown, optics 230 may be disposed between the DMD 220 and the vat 240 so that the UV radiation impinging on the vat 240 passes through the optics 230. Similar to the above embodiment, a blade 250 is used to may be used to sweep additional photopolymer over the completed layer within the vat 240 or to level the material present. The portion of the vat 240 in which the object is being created may be illuminated by a low power backlight 260 disposed on a building platform 270 on a load cell 280. The manufactured object 290 may be removed once the instructions are completed.

The technique shown in FIG. 2 thus may permit a higher throughput, although more support structure may be used than in the embodiment shown in FIG. 1. This may permit smaller objects to be created with reduced cost and higher precision.

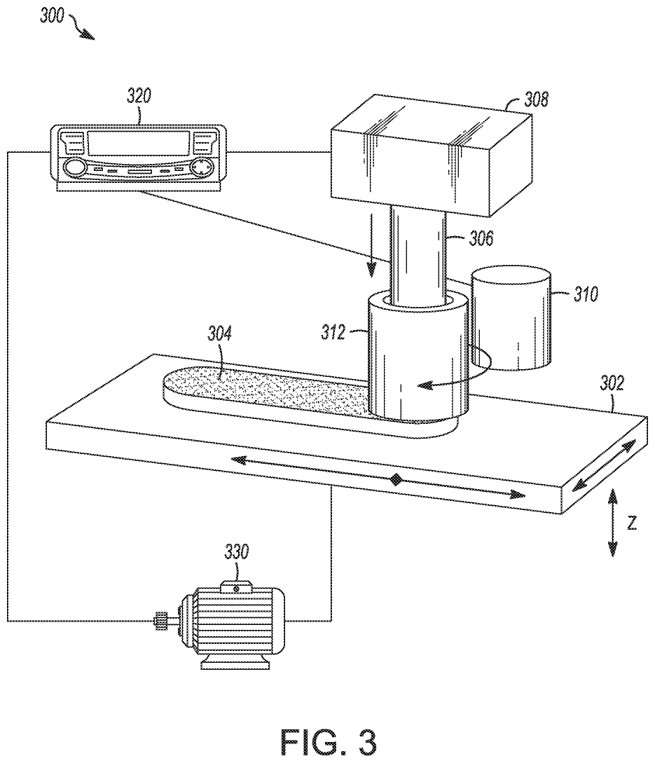

FIG. 3 shows a 3D material jetting apparatus, according to another example embodiment. Only some of the components are shown, for convenience, in the apparatus 300. As above, instructions for creation of the object to be created are provided to a controller 320, which may control both deposition of the deposition material 304 (e.g., ceramic) and movement of a stage 302 based on the instructions from the CAD design. In particular, the controller 320 may control a motor 330, which may move the stage 302 in the xy directions parallel with a single layer of material, as well as the z direction to engage and disengage the stage 302 with the nozzle 312 and move to deposit the next layer of additive material 304.

Following the instructions, once the stage 302 has been moved to the desired location, the controller 320 may trigger the additive material reservoir 308 to release the additive material 304 contained therein. The additive material 304 may be provided through a flexible tube 306 and then be extruded from a nozzle 312 to form the desired layer. Alternatively, the controller 320 may control a port of the nozzle 312 to open or close to deposit the additive material 304 on the stage 302. Although not shown, the nozzle 312 may be mounted on an arm whose movement is controlled by the controller 320. In some embodiments, the nozzle 312 may be heated.

As shown, a UV source 310 may also be controlled by the controller 320 to move to a desired location to harden or partially harden the current layer of additive material 304. The hardening of the current layer may be performed during or after deposition of the current layer. After the stage 302 (and/or arm) is moved to raster the successive layers of the additive material 304, whether or not hardened by the UV source 310, the final green part may be placed into an oven and sintered.

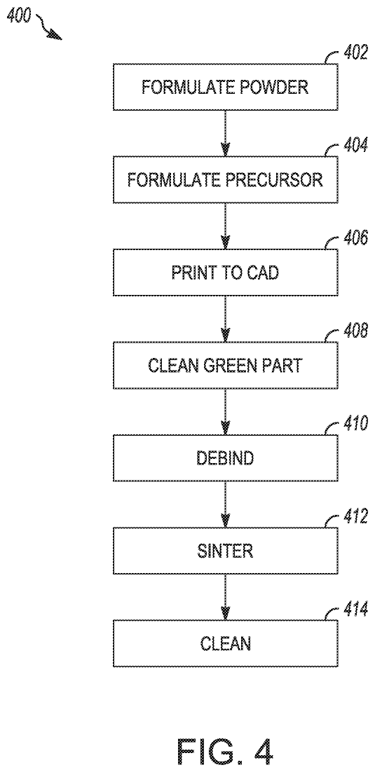

FIG. 4 shows a flowchart of AM, according to another example embodiment. The method 400 shown in FIG. 4 may be used in any of the embodiments described above and may have additional operations and/or some of the operations described may be eliminated. At operation 402, the composition of the powder to create the injector (or another component) may be formulated. In some embodiments, the gas injector may be formed from a ceramic, such as one or more of alumina yttria-stabilized zirconia (YSZ), yttria and single-phase yttrium-aluminum-garnet (YAG). In some embodiments, the ceramic may be YSZ, which is 3% Y₂O₃ stabilized ZrO₂. In addition to formation of the ceramic injector, the same AM technique may be used to form other uncoated chamber parts, including rings and gas nozzles, among others. Once the particular powder is formulated for the ceramic component, the powder may be used to print the ceramic.

Similarly, at operation 404, the composition of the ceramic precursor and curable resin to create the AM layer may be selected. The ceramic precursor may be selected, for example, based on the environment in which the ceramic component is used. The ceramic precursor may contain, for example, a powder and/or liquid preceramic inorganic polymer such as polysilazanes, polycarbosilanes, polysilanes, polysiloxanes, polycarbosiloxanes, polyaluminosilazanes, polyaluminocarbosilanes, boropolycarbosiloxanes. The ceramic precursor may also contain a binder such as that described below. For example, the precursor may include a majority (e.g., about 75%-about 90%, such as about 85%) of the intended ceramic and a minority of a UV/Photoreactive (e.g., about 10%-about 25%, such as about 15%) bonding material of the total blend. A majority of the shrinkage in the structure after processing as a result of removing the, sag about 15%, bonding material.

Regardless of the AM technique used, after determining the component to be created by AM, the injector design may be created using CAD software. The design may then be translated for, and sent to, the AM device. In some embodiments, the instructions for the AM of the injector may be transmitted wirelessly, using Wi-Fi or another wireless protocol. In other embodiments, the AM device may be attached to the design device. After transmitting the instructions, the AM device may directly fuse the powder together using a laser or electron beam as above. Alternatively, the particles of the powder may be initially stuck together to create a desired geometry before performing a secondary heat treatment process to fuse the particles stuck together. As described above, vat photopolymerization may be used, in which a mixture of ceramic grains and photosensitive binder provided from a reservoir is exposed to a laser or other light source to build a layer, which may subsequently be coated with more of the mixture from the reservoir before the next layer is built. In other embodiments, an inkjet style head may selectively deposit a binder, such as an organic liquid binder (e.g., a butyral, polymeric or polyvinyl resin) or wax (e.g., paraffin, carnauba or polyethylene), to temporarily glue the particles together. The hinder may then be partially cured using heat or UV light, followed by deposition of the next layer of powder. Independent of the specific AM process used, the process may be repeated until the component shape has been created at operation 406. In some embodiments, a 3D printer with multiple nozzles may be used in which one nozzle is used to deposit the ceramic and another deposits the binder.

The intermediate component created is referred to as a green part, which is relatively fragile; the particles are hound together sufficiently to be able to retain the component shape, but this shape is able to be easily broken apart because the individual particles are not physically fused to each other. At this point, as shown in operation 408, the green part may be cleaned of excess uncured powder or other impurities.

After cleaning the green part, debinding is used on the cleaned green part in operation 410. That is, the binder is removed by placing the green part in a curing oven for a secondary curing, after which the green part may be removed from the powder bed. If an organic binder is used, such binders typically burn off at 200-300° C.

After debinding the green part, the green part may be sintered at operation 412. Sintering may occur at a much higher temperature than curing (>1000° C.). The particles may be sintered in an inert environment (e.g., N₂) or vacuum. During sintering, the individual powder particles form bonds to create a continuous single structure. As a result of removal of the binder and bonding of the particles associated with the bond formation, shrinkage may occur due to the removal of space between the particles. This shrinkage may be considered in the initial CAD design of the injector.

After sintering, the finished injector (or other component) may again be cleaned at operation 414. This cleaning may be used, for example, to remove hinder remaining after the debinding, which may be carbonized due to the sintering process. Such cleaning may include rinsing the component with deionized water and/or isopropyl alcohol among others.

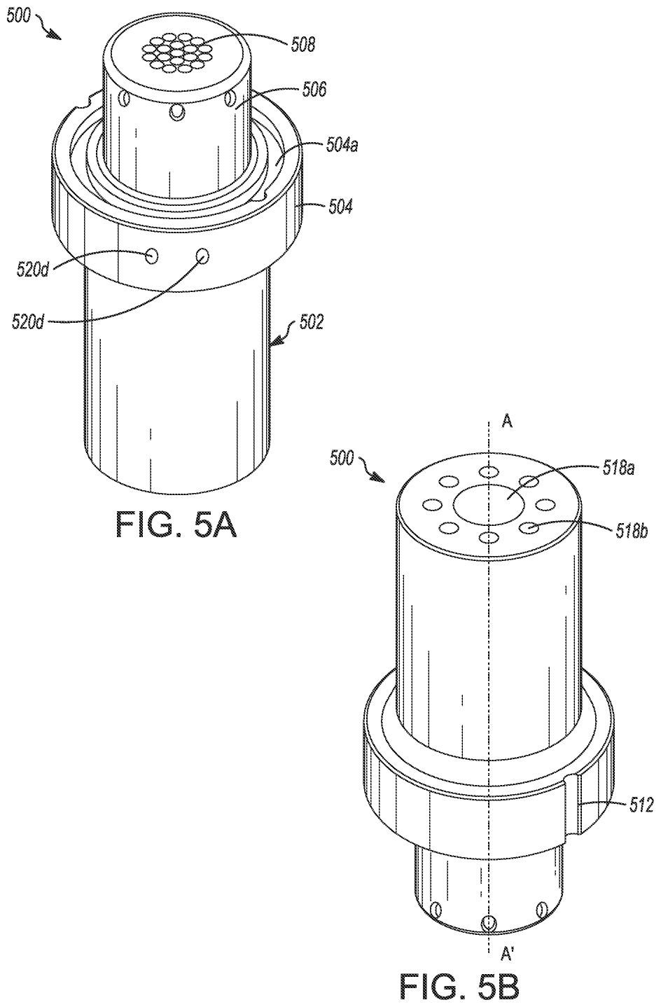

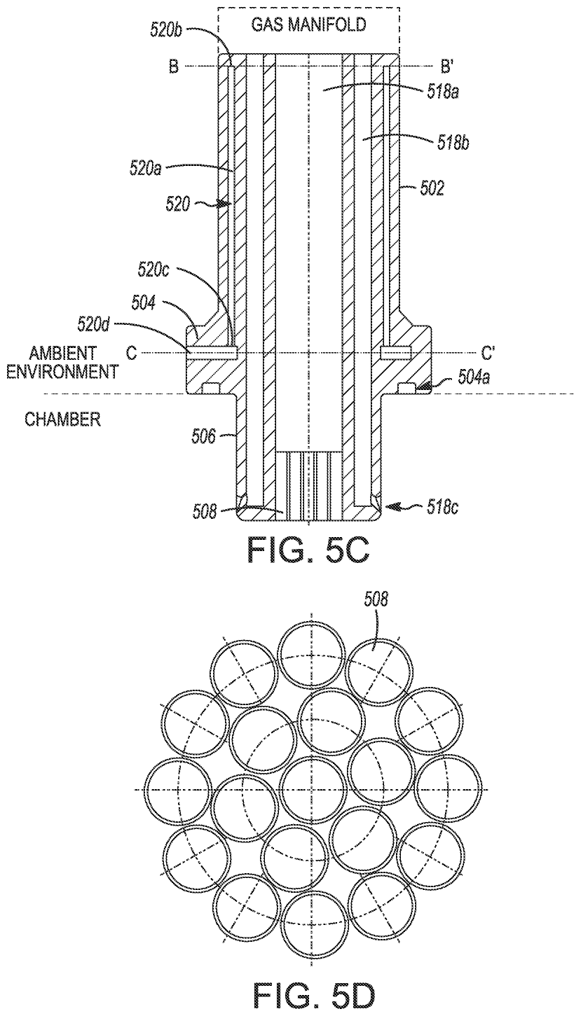

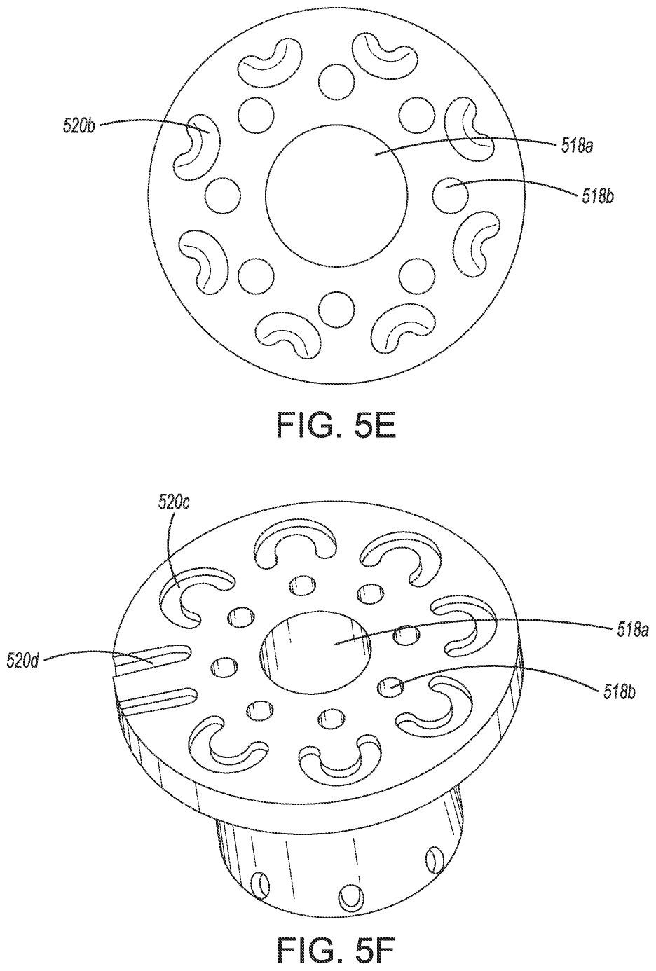

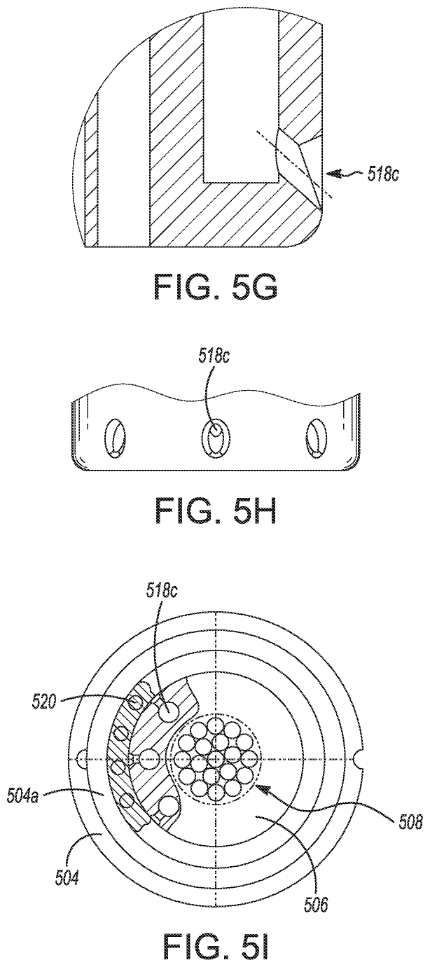

FIGS. 5A-5I show various views of a gas injector created using an AM process, according to another example embodiment. In particular, FIG. 5A shows a bottom perspective view of the gas injector 500, FIG. 5B shows a top perspective view of the gas injector 500, FIG. 5C shows a cross-sectional view of the gas injector 500, FIG. 5D shows an enlarged view of a bottom of the gas injector 500, FIG. 5E shows a cross-sectional view of the gas injector 500 along line B-B′ shown in FIG. 5C, FIG. 5F shows a cross-sectional view of the gas injector 500 along line C-C′ shown in FIG. 5C, FIG. 5G shows a cross-sectional view of a portion of the bottom of the gas injector 500, FIG. 5H shows a side view of the portion of the gas injector 500, and FIG. 5I shows a bottom view of the gas injector 500. The gas injector 500, as shown in FIG. 5A and FIG. 5B, may be formed, as above, from a ceramic (e.g., Y₂O₃, YSZ) using one of the above AM processes. Note that one or more protective coatings such as plasma sprayed ceramics may be added to the gas injector 500 to protect the gas injector 500 from corrosive gasses flowing therethrough when the gas injector 500 is installed in a processing chamber. The gas injector 500 may contain several features, including an inlet portion 502, an outlet portion 506 and a collar 504 between the inlet portion 502 and the outlet portion 506.

The collar 504 may, as shown, contain a coupling mechanism 504a to allow the gas injector 500 to be secured within the processing chamber such that the collar 504 seals an inlet hole of the processing chamber. The collar 504 and inlet portion 502 may be external to the processing chamber (the inlet portion 502 connecting to a gas manifold through which processing gasses are introduced to the gas injector 500), while the outlet portion 506 is disposed within the processing chamber. The coupling mechanism 504a may include one or more grooves that interlock with projections in the processing chamber. The collar 504 may contain a groove 512 for sealing the collar 504 to a connecting structure. The collar 504 may also include holes 520d that connect to conformal channels 520 within the inlet portion 502, as described in more detail below.

As shown, the inlet portion 502 may be about twice the length of the outlet portion 506, although this may depend on parameters such as the design of the chamber and the dynamics of the gas flow within the chamber. The inlet portion 502 may, in some embodiments, have a larger diameter than that of the outlet portion 506. For example, in some embodiments, the inlet portion 502 may have a diameter about 30% larger than the diameter of the outlet portion 506. The inlet portion 502 may contain an inlet hole 518a (or central bore) through which gasses used during semiconductor processing are introduced to the gas injector 500. Similarly, the outlet portion 506 may contain outlet holes 508 from which the gasses exit from the gas injector 500 and thus from which a plasma may be created to interact with the semiconductor wafer thereunder. In other embodiments, the inlet portion 502 may have the same diameter as that of the outlet portion 506.

FIG. 5C shows a cross-sectional view of the gas injector 500 along line A-A′ shown in FIG. 5B. The inlet hole 518a, as shown in FIG. 5C. may be connected to the outlet holes 508. Each of the outlet holes 508 may have a smaller diameter than the inlet hole 518a and may be arranged to have, in aggregate, substantially the same diameter as the inlet hole 518a. FIG. 5D shows an enlarged view of a bottom of the gas injector 500 in which the outlet holes 508 are shown as being arranged in a honeycomb (or hexagonal close-packed) structure in which the outlet holes 508 of the innermost circle is a single outlet hole 508. That is, as illustrated, in some embodiments, the outlet holes 508 are arranged in concentric circles in which the center of the outlet holes 508 of the outermost circle are separated by about 30°, the center of the outlet holes 508 of the middle circle are separated by about 60°, and thus the offset between the center of the outlet holes 508 of the outermost circle and the middle circle are offset by about 15°. As shown in FIG. 5C, the outlet holes 508 may extend from an end (or face) of the outlet portion 506 toward a center of the gas injector 500 in the cavity defined by the inlet hole 518a. In some embodiments, the outlet holes 508 may extend from the end of the outlet portion 506 about 50-60% of the total length of the outlet portion 506.

In addition to the inlet hole 518a, the end of the inlet portion 502 may also contain one end (top end) of secondary inlet holes 518b. Similarly, as shown in FIGS. 5G and 5H, the outlet portion 506 may also contain secondary outlet holes 518c associated with the secondary inlet holes 518b. Unlike the inlet portion 502, whose end contains the top end of the secondary inlet holes 518b however, the side of the outlet portion 506 contains bottom ends of the secondary outlet holes 518c. That is, the end of the outlet portion 506 may contain only the ends of the outlet holes 508.

As best shown in the enlarged view of FIG. 56, the bottom end of each of the secondary outlet holes 518c is provided at a non-right angle from the sidewall of the outlet portion 506. This allows for different gasses to be provided to the inlet hole 518a (and thus the outlet holes 508) than to the secondary inlet holes 518b (and thus the secondary outlet holes 518c). This angle may be, for example, about 45° from normal to the surface of the sidewall (and thus also from the end) of the outlet portion 506. The secondary inlet holes 518b may be disposed, as shown, uniformly around the inlet hole 518a in a circle (i.e., equidistant from the center of the central bore and each secondary inlet hole 518b equiangular from each adjacent secondary inlet hole 518b), while the secondary outlet holes 518c are formed uniformly around the outlet portion 506. While eight secondary inlet holes 518b are present in the embodiment shown, thus surrounding the inlet hole 518 at 45° increments, other numbers of secondary inlet holes 518b (and corresponding secondary outlet holes 518c) may be used. The symmetric spacing of the outlet holes 508 and secondary outlet holes 518c may provide more uniformity in gas distribution, and thus plasma, within the processing chamber.

As discussed above, in a gas injector created by subtractive manufacturing, damage (micro-cracks) having a DoD of about 15-50 microns is formed due to the lateral compressive stain in the structure when machining, such machining may include drilling of the various holes in the gas injector. This micro-damage is unable to be detected by the human eye during inspection of the gas injector. However, the DoD may continue to increase during operation in the processing chamber due to several mechanisms. For example, the DoD increases due to thermal cycling of the gas injector during operation of the processing chamber in which the gas injector is disposed. In addition, the use of corrosive gasses, such as the halogens, used during semiconductor processing may exacerbate attack by the corrosive gasses. This is to say that the corrosive gasses may seep through the micro-cracks in the ceramic to increase the DoD. The combination of these forces, among others potentially, may result in delamination of the structure (and/or coating). This may in turn cause material to fall into the processing chamber and potentially on one or more of the wafers being processed.

To combat this, the additive manufactured gas injector 500 may also contain one or more conformal channels as shown in FIGS. 5B-5C, 5E-5F and 51. In particular, FIG. 5E shows a cross-sectional view of the gas injector 500 along line B-B′ shown in FIG. 5C and FIG. 5F shows a cross-sectional view of the gas injector 500 along line C-C′ shown in FIG. 5C. Although the use of conformal channels may add complexity to the design and fabrication process, the conformal channels may be added due to the limitations inherent in the AM process. In particular, in some embodiments, the thickness of a continuous structure created using AM may be limited to less than about 6 mm due to limitations in the AM processes. As the thickness of the gas injector 500 may exceed this (e.g., the thickness of the wall of the inlet portion 502 may be >about 6 mm), the conformal channels may be added to provide the desired reduction in ceramic material thickness while still maintaining integrity of the structure. For example, the gas injector 500 may include a structure such as about 4 mm material, about 2 mm conformal channel, and about 4 mm material, thereby permitting the gas injector 500 to be manufactured using an AM process. That is, the conformal channel may be disposed such that at least one dimension of the surrounding material is less than about 6 mm.

Accordingly, the conformal channel 520 may extend throughout the inlet portion 502 and into the collar 504 as shown in FIG. 5C. As illustrated, the conformal channel 520 does not extend into the outlet portion 506 as, for example, the diameter of the wall outlet portion 506 may be smaller than 4 mm. Thus, the conformal channel 520 may be disposed only outside of the chamber. In the embodiment shown in FIG. 5C, the conformal channel 520 may extend around substantially the entire perimeter of the inlet portion 502 and the collar 504. The conformal channel 520 may contain channel sections 520a, inlet channel ends 520b, collar channel ends 520c, and channel ports 520d.

In particular, as illustrated in FIGS. 5C, 5E, and 5F, the channel sections 520a may terminate in the inlet channel ends 520b before reaching the end (face) of the inlet portion 502 and may terminate in the collar channel ends 520c before reaching the end of the collar 504 adjacent to the outlet portion 506. Moreover, the channel sections 520a may terminate in the collar channel ends 520c before reaching a portion of the gas injector 500 to be inserted into the chamber (i.e., the outlet portion 506). The channel sections 520a may, like the inlet hole 518a and secondary inlet holes 518b, be substantially cylindrical. The diameter of the channel sections 520a may be minimally sized to retain the integrity of the structure of the gas injector 500, having, for example, a diameter smaller than or equal to the diameter of the secondary inlet holes 518b.

As shown in FIGS. 5E and 5F, opposing., ends of the channel sections 520a may be connected. In particular, as shown in FIG. 5E, each inlet channel end 520b may be disposed substantially between a different pair of adjacent secondary inlet holes 518b. Each channel section 520a and corresponding inlet channel end 520b may be disposed at a larger diameter from the center of the inlet portion 502 than the secondary inlet holes 518b. In the embodiment shown in FIG. 5E, the inlet channel end 520b may have an arcuate shape whose apex is disposed more proximate to the center of the inlet portion 502 than the ends of the inlet channel end 520b. In other embodiments, the inlet channel end 520b may have an arcuate shape reversed from that shown (i.e., the apex is disposed more distal to the center of the inlet portion 502 than the ends), another curved shape or may be straight.

As shown in FIG. 5E, adjacent pairs of channel sections 520a may be connected by an inlet channel end 520b. That is, as illustrated, alternating adjacent pairs of channel sections 520a may be connected by a unique inlet channel end 520b, with all but one of the adjacent pairs of channel sections 520a that are not connected by one of the inlet channel ends 520b connected at the collar 504, as shown in FIG. 5F. Similar to the inlet channel end 520b, the collar channel ends 520c may have an arcuate shape in which the apex is disposed more distal to the center of the inlet portion 502 than the ends. That is, the collar channel ends 520c may have an arcuate shape reversed from that of the inlet channel end 520b. As above, the collar channel ends 520c may have another curved shape or may be straight. As illustrated, each collar channel end 520c may be disposed substantially around a different pair of adjacent secondary inlet holes 518b. More specifically, the arcuate shape of one or the collar channel ends 520c may be centered around a corresponding one of the secondary inlet holes 518b. Like the inlet channel ends 520b, the entirety of each collar channel end 520c may be disposed at a larger diameter from the center of the inlet portion 502/collar 504 than the secondary inlet holes 518b.

While most of the channel sections 520a terminate in the collar channel ends 520c, one pair of the channel sections 520a may instead terminate in a pair of channel ports 520d. The channel ports 520d may be extend to the outer diameter of the collar 504, thereby permitting the conformal channel 520 to be cleaned after fabrication by flushing the conformal channel 520 with, for example, deionized water and isopropyl alcohol. While the channel ports 520d are shown as being adjacent to each other, in other embodiments, the channel ports 520d may disposed anywhere along the perimeter of the collar 504.

Note that although only one conformal channel 520 is described above, in other embodiments multiple separate conformal channels 520 may be used. In this case, each conformal channel 520 may cover the same angular range around the gas injector 500, or at least one of the conformal channels 520 may have a different angular range than at least one other of the conformal channels 520. For example, if three independent conformal channels 520 are used, each can extend over about 120° around the inlet portion 502 of the gas injector 500, or at least one of the conformal channels 520 can extend over less than about 120° around the inlet portion 502 of the gas injector 500 while at least one of the conformal channels 520 can extend over greater than about 120° around the inlet portion 502 of the gas injector 500. Each conformal channel 520 may terminate in an independent pair of channel ports 520d (that is, no two conformal channels 520 may share at least one channel port 520d).

FIG. 5I shows a view of a bottom of the gas injector 500 in which the outlet holes 508 and secondary outlet holes 518c in the outlet portion 506 are shown as being surrounded by the conformal channels 520. In FIG. 51. the collar 504 forms the outermost ring (i.e., has the largest diameter), with succeeding inward rings being the groove 504a, and the outlet portion 506, with the outlet holes 508/inlet hole 518 forming the innermost ring. The secondary outlet ports 518c are shown as one cutaway area of the outlet portion 506 in FIG. 5I, while the conformal channel 520 shown as another cutaway area of the collar 504. In some embodiments, as shown in FIG. 5C, the diameter of the inlet hole 518 may be about ½ that of the outlet portion 506.

In some embodiments, the channel ports 520d may reside in the inlet portion 502 rather than in the collar 504, such as at the end of the conformal channel 520 most proximate to the face of the inlet portion 502 (although the channel ports 520d may reside anywhere along the conformal channel 520). In addition, although FIG. 5C illustrates that the conformal channel 520 does not extend into the outlet portion 506, in other embodiments however, the conformal channel 520 may extend into the outlet portion 506. This may be the case, for example, if the diameter of the wall of the outlet portion 506 exceeds 4 mm. In such an embodiment, the channel ports 520d may reside in the collar 504 or in the inlet portion 502 or outlet portion 506.

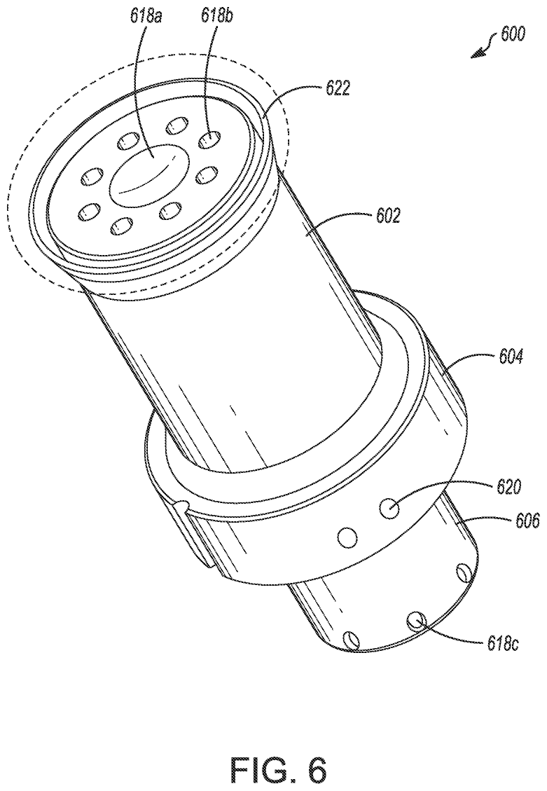

FIG. 6 shows a perspective of a gas injector according to another embodiment. The gas injector 600 consolidates an adjacent part (connector 622) in a front end of the gas injector 600. The gas injector 600, like that shown in FIGS. 5A-5I, may contain an inlet portion 602 to be positioned outside the processing chamber and to which processing gasses are introduced via a gas manifold (not shown in FIG. 6), an outlet portion 606 to be disposed in the processing chamber and from which processing gasses are injected into the processing chamber, and a collar 604 between the inlet portion 602 and the outlet portion 606. The inlet portion 602 may contain an inlet hole 618a and secondary inlet holes 618b encircling the inlet hole 618a. The inlet hole 618a may be connected to outlet holes 508 (not shown in FIG. 6) disposed at an end of the outlet portion 606 having a honeycomb arrangement; the secondary inlet holes 618b may be connected to secondary outlet holes 618c disposed in a sidewall of the outlet portion 606. The gas injector 600 may also contain a conformal channel, whose ports 620 are disposed in the sidewall of the collar 604. The gas injector 600 may thus have a structure similar to the gas injector 500 shown in FIGS. 5A-5I.

In addition, the gas injector 600 contains a connector 622 that is integrated with the above-described portions of the gas injector 600. In practice, gas injectors may use such a connector 622 to seal the gas injector and the gas manifold. However, due to a difference between the materials used to form the gas injector and that used to form the connector 622 and/or due to the increased processing complexity (among others), the connector 622 and the gas injector are typically created in entirely different manufacturing processes at different times. This leads to an increase in costs and number of parts. Despite the inability to create such a connector 622 when subtractive manufacturing processes are used, the use of AM may permit the gas injector and connector 622 to be a single, integral component.

Several differences may exist between a gas injector formed by AM processes and that formed by subtractive manufacturing processes. Micrographs of the honeycomb output holes, the center bore in which the output holes are disposed, and the secondary output holes formed by subtractive manufacturing processes all illustrate fractures extending up to about 10 microns and material having a wide range of porosity, with pores having a diameter ranging from <0.25 microns to >1 micron. While the largest number of pores are <0.25 microns, a substantial number of pores are >1 micron. In comparison, micrographs of the honeycomb output holes, the center bore in which the output holes are disposed, and the secondary output holes formed by AM processes all illustrate no observable surface damage (i.e., much less than 1 micron) and a much greater number of pores than the gas injector formed by subtractive manufacturing processes but having a smaller range of porosity, with almost all pores having a diameter <0.25 microns. That is, after fabrication and prior to operation, the gas injector formed by AM processes contain substantially no damage. The amount of porosity in the gas injector formed using the AM process may, in some cases, be reduced by altering the sintering procedure. The average grain size of gas injectors fabricated by the AM process was 0.32 microns (YSZ), compared to >1 micron for the subtractive manufacturing process (1.25, 2.34 or 18.48 microns, depending on the manufacturer). Ceramic additive powders are controllable to the sub-micron range, which may be beneficial for any post AM process, such as polishing.

The surface morphology of the center bore of both Yana and Alumina gas injectors formed by subtractive manufacturing processes also show similar amounts of damage to the surface of the center bore as the micrographs. Similarly, the surface morphology of the center bore formed by the AM process show relatively no amount of damage to the surface of the center bore, with a few mountain-like features that may be powder agglomeration during the AM process. The measurements of the surface roughness of both the outer and inner surfaces of the gas injector using a contact profilometer showed a roughness of about 25 micron-in for the output face, about 60 micron-in for the output holes and about 40 micron-in for the output face for gas injectors fabricated by both the subtractive manufacturing process and AM process.

Other measurements of gas injectors fabricated by the AM process, as provided in the embodiments described above, show similar or better features than that of gas injectors fabricated by the subtractive manufacturing process. Energy Dispersive X-Ray Analysis (EDX) on the face of the honeycomb showed a uniform composition across the entire surface. In addition, although gas injectors formed using the AM process may be cleaned after fabrication (e.g., using deionized water and isopropyl alcohol), such gas injectors are relatively clean compared to gas injectors formed using the subtractive manufacturing process, which are subject to more stringent cleaning with degreasers and other cleaners due to the machine oil and grease used in the subtractive manufacturing processes. Similarly, after 200 rf hours in a high bias (e.g., 1000V) environment using a mixture of HBr, HCl₂, H₂ and CFₓ gas injectors fabricated by the AM process showed at most minimal erosion compared to gas injectors fabricated by the subtractive manufacturing process.

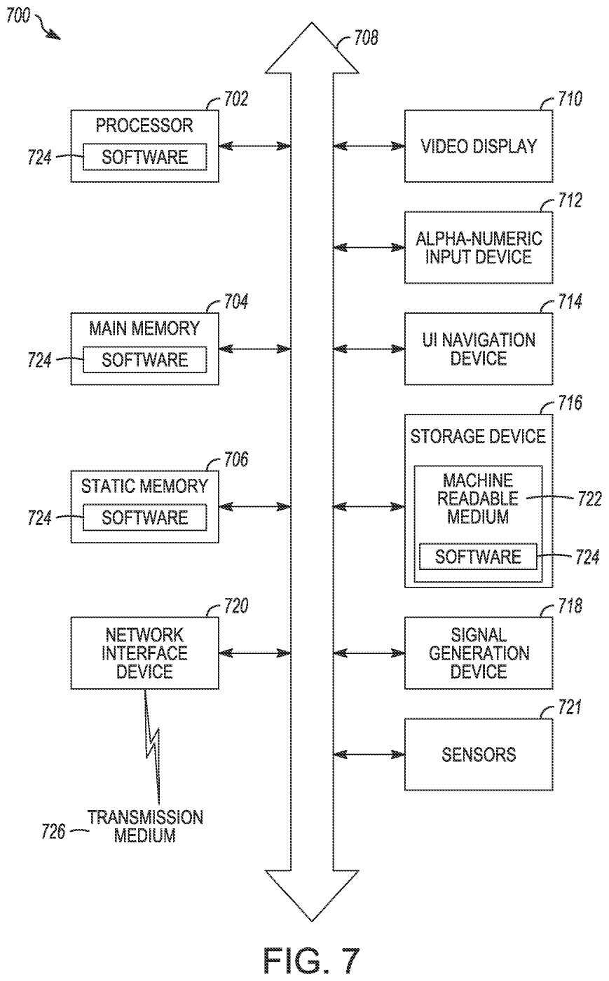

FIG. 7 is a machine associated with additive manufacturing of a component, according to an example embodiment. The machine 700 can be an additive processing machine used to create the component (gas injector) or may be an additive processing machine created by the component. Examples, as described herein, may include, or may operate by, logic, a number of components, or mechanisms. Circuitry is a collection of circuits implemented in tangible entities that include hardware (e.g., simple circuits, gates, logic, etc.). Circuitry membership may be flexible over time and underlying hardware variability. Circuitry includes members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, by moveable placement of invariant massed particles, etc.) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 700 may include a hardware processor 702 (e.g., a central processing unit (CPU), a hardware processor core, or any combination thereof), a graphics processing unit (GPU) (which may be part of the CPU or separate), a main memory 704, and a static memory 706, some or all of which may communicate with each other via a link (e.g., bus) 708. The machine 700 may further include a display 710, an alphanumeric input device 712 (e.g., a keyboard), and a user interface (UI) navigation device 714 (e.g., a mouse). In an example, the display 710, alphanumeric input device 712, and UI navigation device 714 may be a touch screen display. The machine 700 may additionally include a mass storage device (e.g., drive unit) 716, a signal generation device 718 (e.g., a speaker), a network interface device 720, and one or more sensors 721. such as a Global Positioning System (GPS) sensor, compass, accelerometer, or another sensor. The machine 700 may include transmission medium 726, such as a serial (e.g., universal serial bus (USB)), parallel, or other wired or wireless (e.g., infrared (IR), near field communication (NFC), etc.) connection to communicate with or control one or more peripheral devices (e.g., a printer, card reader, etc.).

The storage device 716 may include a machine-readable medium 722 on which is stored one or more sets of data structures or instructions 724 (referred to as software) embodying or utilized by any one or more of the techniques or functions described herein. The instructions 724 may also reside, completely or at least partially, within the main memory 704, within the static memory 706, within the hardware processor 702, or within the GPU, during execution thereof by the machine 700. In an example, one or any combination of the hardware processor 702, the GPU, the main memory 704, the static memory 706, or the mass storage device 716 may constitute machine-readable media 722.

While the machine-readable medium 722 is illustrated as a single medium, the term “machine-readable medium” may include a single medium or multiple media (e.g., a centralized or distributed database, and/or associated caches and servers) configured to store the one or more instructions 724.

The term “machine-readable medium” may include any medium that can store, encode, or carry the instructions 724 for execution by the machine 700 and that cause the machine 700 to perform any one or more of the techniques of the present disclosure, or that can store, encode, or carry data structures used by or associated with such instructions 724. Non-limiting machine-readable medium 722 examples may include solid-state memories, and optical and magnetic media. In an example, a massed machine-readable medium comprises a machine-readable medium 722 with a plurality of particles having invariant (e.g., rest) mass. Accordingly, massed machine-readable media are not transitory propagating signals. Specific examples of massed machine-readable media may include non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; and CD-ROM and DVD-ROM disks. The instructions 724 may further be transmitted or received over a communications network using a transmission medium 726 via the network interface device 720.

The processor 702, in conjunction with the memories 704, 706, may be used, for example, to operate the fabrication equipment described above to create the gas injector described in any of the embodiments above. The display 710, alphanumeric input device 712, UI navigation device 714, and signal generation device 718 may be used to notify the operator as to processes of the cleaning, including completion or errors, as well as approximate amount of removal for each cleaning apparatus, perhaps using the sensors 721. The information may be provided to an operator (e.g., mobile device of the operator) via the network interface device 720. All of the mechanisms may be controlled when the instructions are 724 are executed by the processor 702.

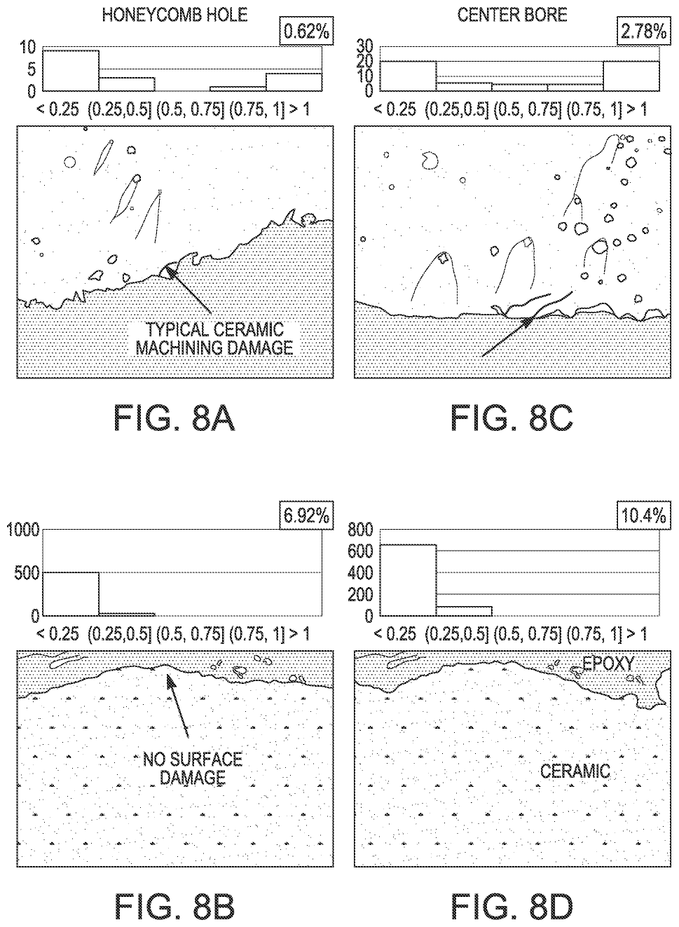

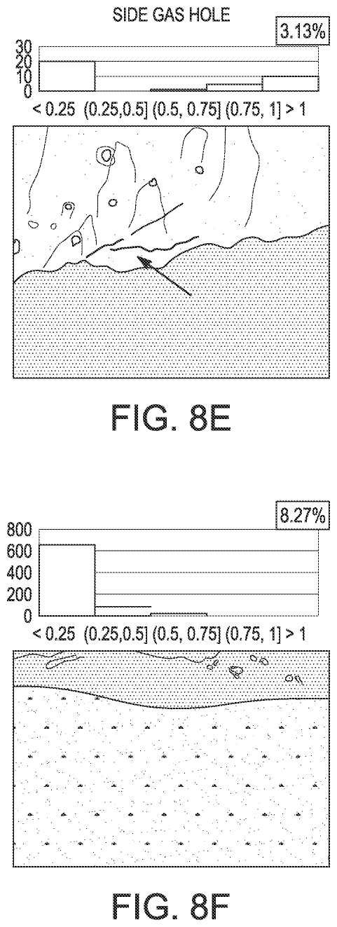

FIGS. 8A-8F show cross-sections of different regions of an injector fabricated by subtractive manufacturing and an injector fabricated by AM, according to an example embodiment. In particular, FIGS. 8A and 8B show cross-sections of one of the secondary inlet holes of an injector fabricated by subtractive manufacturing and an injector fabricated by AM, respectively. Similarly, FIGS. 8C and 8D show cross-sections of the inlet hole of an injector fabricated by subtractive manufacturing and an injector fabricated by AM, respectively. FIGS. 8E and 8F show cross-sections of one of the secondary outlet holes of an injector fabricated by subtractive manufacturing and an injector fabricated by AM, respectively. As can be seen, the porosity of the sections in the subtractive manufacturing injectors in each of FIGS. 8A, 8C, and 8E has a substantially binary distribution of pores having diameters of <about 0.25 μm and >about 1 μm with about 0.6% to about 3.1% of the total volume measured having pores. On the other hand, the diameter of the pores of the samples in the AM injectors in each of FIGS. 8B, 8D, and 8F are primarily <about 0.25 μm in diameter with about 7% to about 10.4% of the total volume measured having pores. In some embodiments, the percent of porosity shown in FIGS. 8B, 8D, and 8F may be addressed with sintering. FIGS. 8A, 8C, and 8E also show a relatively large amount of machining damage (DoD), evidenced by the cracks in these figures, that contribute to the influx of particulate into the processing chamber. As is clearly apparent, no cracks (and thus no DoD) are present in the AM injector shown in FIGS. 8B, 8D, and 8F.

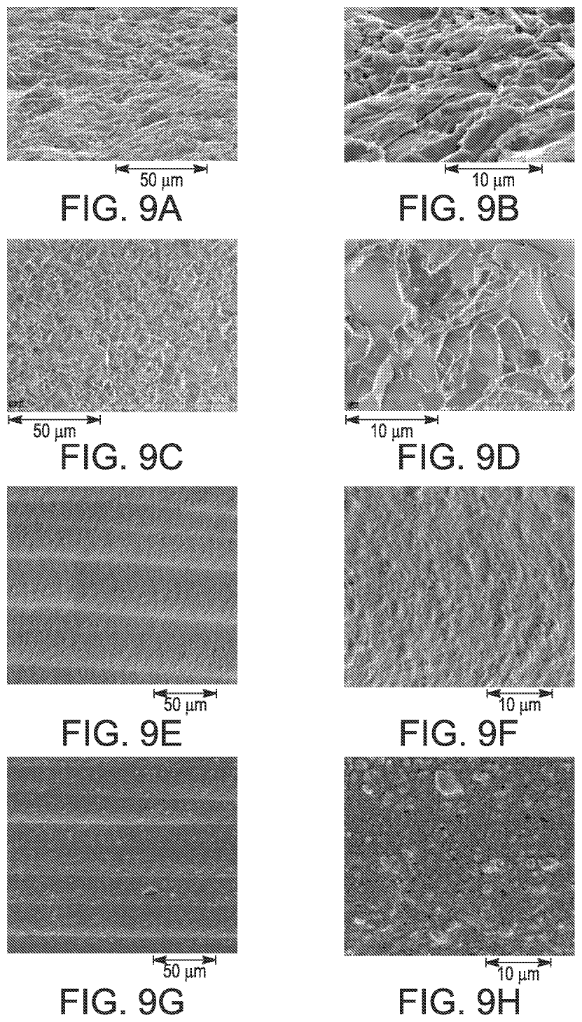

FIGS. 9A-9F show surface morphology of an inlet hole of an injector fabricated by subtractive manufacturing and an injector fabricated by AM, according to an example embodiment. FIGS. 9A and 9B show the surface morphology of an inlet hole of an yttria injector fabricated by subtractive manufacturing at different resolutions, with FIG. 9B being at 5× magnification compared with FIG. 9A; the scale shown in FIG. 9A being 50 μm and in FIG. 9B being 10 μm. Similarly, FIGS. 9C and 9D show the surface morphology of an inlet hole of an alumina injector fabricated by subtractive manufacturing at the same different resolutions, with FIG. 9C being at 5× magnification compared with FIG. 9D; the scale shown in FIG. 9C being 50 μm and in FIG. 9D being 10 μm.

FIGS. 9E and 9F show the surface morphology of an inlet hole fabricated by AM at the same resolutions as those above (FIG. 9F at 5× magnification compared with FIG. 9E). Similarly, FIGS. 9G and 9H show the surface morphology of a secondary outlet hole fabricated by AM at the same resolutions (FIG. 9G at 5× magnification compared with FIG. 9H).

As seen, the surfaces in the micrograph shown in FIGS. 9A-9D are relatively rough and contains numerous cracks compared with the surface shown in the micrographs shown in FIGS. 9E-9H. The surface roughness and cracks shown in FIGS. 9A-9D may be attributed to damage caused by the machining of the ceramic surface. There are several mountain-like features observable in FIGS. 9E-9H, which may be the result of powder agglomeration during printing. In some embodiments, such mountain-like features may be mitigated by introducing a polishing operation to the injector after AM fabrication (also referred to as a post polishing process).

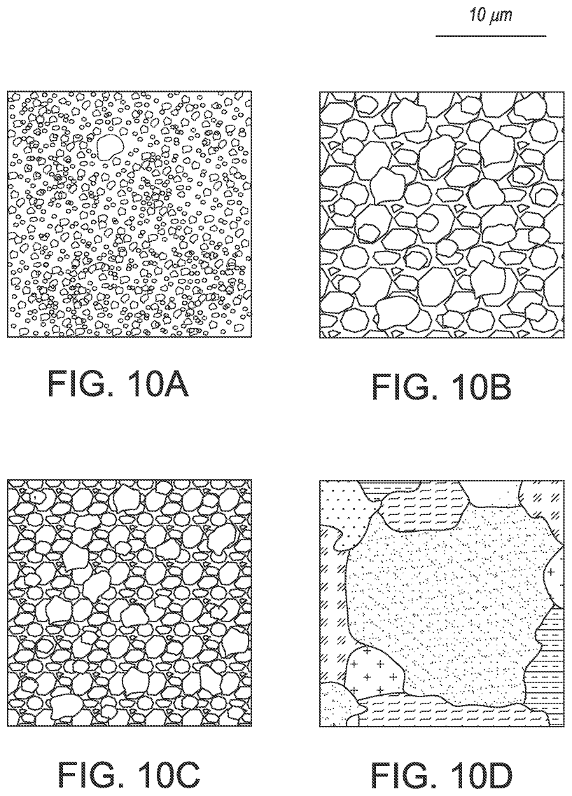

FIGS. 10A-10D show grain sizes an injector fabricated by subtractive manufacturing and fabricated by AM, according to an example embodiment. In particular, FIG. 10A shows grain sizes of a YSZ AM injector, FIGS. 10B-10D show grain sizes of Y₂O₃ injectors from different suppliers fabricated by subtractive manufacturing, whose grain sizes are similar to that of a YSZ injector fabricated by subtractive manufacturing. As can be seen, the average grain sizes of the YSZ AM injector are substantially smaller (about 0.3 μm) than that of Y₂O₃ injectors fabricated by subtractive manufacturing (about 2.3 μm for the Y₂O₃ injector of FIG. 10B, about 1.25 μm for the Y₂O₃ injector of FIG. 10C, and about 18.5 μum for the Y₂O₃ injector of FIG. 10D). Thus, as indicated previously, average sub-micron grain sizes may be achieved by using AM processes, which may be beneficial in any post process, such as polishing.

### ADDITIONAL NOTES AND EXAMPLES

Example 1 includes a gas injector comprising: an inlet portion including an inlet hole on an inlet face of the inlet portion, the inlet portion to receive a processing gas introduced via the inlet hole during semiconductor processing, the inlet portion further including a conformal channel disposed between the inlet hole and a sidewall of the inlet portion, an outlet portion including an outlet hole from which the processing gas is provided from the gas injector during the semiconductor processing, the outlet hole connected to the inlet hole; and a collar disposed between the inlet portion and the outlet portion, the collar having a larger diameter than the inlet portion and the outlet portion, the conformal channel extending into the collar.

Example 2 includes the subject matter of Example 1 wherein the conformal channel has a plurality of channel sections each of which extends through the inlet portion and terminates at inlet channel ends before reaching the inlet face.

Example 3 includes the subject matter of Example 2 wherein each channel section also terminates at collar channel ends before reaching the outlet portion.

Example 4 includes the subject matter of any one or more of Examples 2-3 wherein alternating adjacent pairs of channel sections are connected via the inlet channel ends such that each inlet channel end is separated from an adjacent inlet channel end, and at least some of adjacent pairs of channel sections not connected via the inlet channel ends are connected via the collar channel ends.

Example 5 includes the subject matter of any one or more of Examples 2-4 wherein the collar further comprises a sidewall having ports connected with at least one of the adjacent pairs of channel sections not connected via the inlet channel ends.

Example 6 includes the subject matter of any one or more of Examples 1-5 wherein the conformal channel is a single channel that extends around substantially an entirety of the inlet hole.

Example 7 includes the subject matter of any one or more of Examples 2-6 wherein at least one of the inlet channel ends or the collar channel ends of each channel section have an arcuate shape.

Example 8 includes the subject matter of any one or more of Examples 1-7 wherein the inlet hole comprises a single inlet central bore and a plurality of secondary inlet holes surrounding the inlet central bore, the secondary inlet holes are equidistant from a center of the inlet central bore, each secondary inlet hole is equiangular from each adjacent secondary inlet hole, the outlet hole comprises a single outlet central bore connected with the inlet central bore and a plurality of secondary outlet holes connected with the secondary inlet holes, the secondary outlet holes are disposed on a sidewall of the outlet portion, and an arc of one of each inlet channel end or each collar channel end is centered angularly around a different secondary inlet hole.

Example 9 includes the subject matter of Example 8 wherein an arc of at least another of each inlet channel end or each collar channel end is centered angularly between adjacent secondary inlet holes.

Example 10 includes the subject matter of Example 8 or Example 9 wherein each channel section has a diameter smaller than a diameter of each secondary inlet bole.

Example 11 includes the subject matter of any one or more of Examples 1-10 and further comprises a connector integrally formed with the sidewall of the inlet portion, the connector sized to be connected to a gas manifold configured to supply the gas to the gas injector, the gas injector formed from a ceramic material.

Example 12 includes the subject matter of any one or more of Examples 1-11 wherein the conformal channel is disposed such that at least one dimension of material of the gas injector surrounding the conformal channel is limited to less than about 6 mm.

Example 13 includes the subject matter of any one or more of Examples 1-12 wherein a depth of damage of the gas injector is less than about 1 micron.

Example 14 includes a method of fabricating a ceramic gas injector, the method comprising: printing, using additive manufacturing equipment, a green part corresponding to the gas injector, the green part comprising a ceramic powder and binder, the green part comprising: an inlet portion comprising a central bore and a conformal channel disposed in a sidewall, the conformal channel terminating before reaching a top face; and a collar disposed between the inlet portion and an outlet portion, the conformal channel extending into the collar and terminating before extending into the outlet portion, the conformal channel disposed such that at least one dimension of material of the gas injector surrounding the conformal channel is limited to less than about 6 mm; debinding the green part to remove the binder; and sintering the green part after the debinding to form the gas injector, the gas injector having a depth of damage less than about 1 micron.

Example 15 includes the subject matter of Example 14 wherein printing the green part further comprises: printing the conformal channel to have a plurality of channel sections each of which extends through the inlet portion and terminates at inlet channel ends before reaching the top face, alternating adjacent pairs of channel sections being connected via the inlet channel ends such that each inlet channel end is separated from an adjacent inlet channel end, and all but one adjacent pair of channel sections not connected via the inlet channel ends being connected via the collar channel ends, and printing the collar to have ports in a sidewall, the ports connected with the one adjacent pair of channel sections not connected via the inlet channel ends.

Example 16 includes the subject matter of Example 14 or Example 15 wherein: the central bore is encircled by secondary inlet holes, and printing the green part further comprises printing the inlet channel ends and the collar channel ends such that an arc of one of each inlet channel end or each collar channel end is centered angularly around a different one of the secondary inlet holes and an arc of at least another of each inlet channel end or each collar channel end is centered angularly between adjacent ones of the secondary inlet holes.

Example 17 includes a semiconductor processing system comprising: a gas manifold configured to supply gasses used during semiconductor processing: a gas injector comprising: an inlet portion coupled with the gas manifold and to which the gasses are to be introduced via an inlet hole on an inlet face of the inlet portion, the inlet portion comprising a conformal channel disposed between the inlet hole and a sidewall of the inlet portion, the inlet hole comprising a single inlet central bore and a plurality of secondary inlet holes surrounding the inlet central bore, the secondary inlet holes equidistant from a center of the inlet central bore, each secondary inlet hole equiangular from each adjacent secondary inlet hole; an outlet portion from which the gasses are provided from the gas injector via an outlet hole connected to the inlet hole, the outlet hole comprising a single outlet central bore connected with the inlet central bore and a plurality of secondary outlet holes connected with the secondary inlet holes, the secondary outlet holes disposed on a sidewall of the outlet portion; and a collar disposed between the inlet portion and the outlet portion, the collar having a larger diameter than the inlet portion and the outlet portion, the conformal channel extending into the collar; and a processing chamber within which a semiconductor wafer is disposed, the gas injector coupled to the processing chamber such that the gasses are provided into the processing chamber from the outlet portion.

Example 18 includes the subject matter of Example 17 wherein the conformal channel has a plurality of channel sections each of which extends through the inlet portion, terminates at inlet channel ends before reaching the inlet face, and also terminates at collar channel ends before reaching the outlet portion.

Example 19 includes the subject matter of Example 18 wherein alternating adjacent pairs of channel sections are connected via the inlet channel ends such that each inlet channel end is separated from an adjacent inlet channel end, at least some of adjacent pairs of channel sections not connected via the inlet channel ends are connected via the collar channel ends, and the collar further comprises a sidewall having ports connected with at least one of the adjacent pairs of channel sections not connected via the inlet channel ends.

Example 20 includes the subject matter of any one or more of Examples 17-19 further comprising a connector integrally formed with the sidewall of the inlet portion, the connector sized to be connected to the gas manifold.

While exemplary aspects of the subject matter discussed herein have been shown and described herein, it will be obvious, to those skilled in the art, that such embodiments are provided by way of example only. Numerous variations, changes, and substitutions will now occur to those skilled in the art, upon reading and understanding the material provided herein, without departing from the scope of the disclosed subject matter. It should be understood that various alternatives to the embodiments of the disclosed subject matter described herein may be employed in practicing the various embodiments of the subject matter.

Accordingly, the specification and drawings are to be regarded in an illustrative rather than a restrictive sense. The accompanying drawings that form a part hereof show, by way of illustration, and not of limitation, specific aspects in which the subject matter may be practiced. The aspects illustrated are described in sufficient detail to enable those skilled in the art to practice the teachings disclosed herein. Other aspects may be utilized and derived therefrom, such that structural and logical substitutions and changes may be made without departing from the scope of this disclosure. This Detailed Description, therefore, is not to be taken in a limiting sense, and the scope of various aspects is defined only by the appended claims, along with the full range of equivalents to which such claims are entitled. It is intended that the following claims define the scope of the disclosed subject matter and that methods and structures within the scope of these claims and their equivalents be covered thereby.

The abstract will allow the reader to quickly ascertain the nature of the technical disclosure. The abstract is submitted with the understanding that it will not be used to interpret or limit the scope or meaning of the claims. In addition, in the foregoing Detailed Description, it can be seen that various features are grouped together in a single aspect for the purpose of streamlining the disclosure. This method of disclosure is not to be interpreted as reflecting an intention that the claimed aspects have more features than are expressly recited in each claim. Rather, as the following claims reflect, inventive subject matter lies in less than all features of a single disclosed aspect. Thus, the following claims are hereby incorporated into the Detailed Description, with each claim standing on its own as a separate aspect.

What is claimed is:

1. A gas injector comprising:
an inlet portion including an inlet hole on an inlet face of the inlet portion, the inlet portion to receive a processing gas introduced via the inlet hole during semiconductor processing, the inlet portion further including a conformal channel disposed between the inlet hole and a sidewall of the inlet portion;
an outlet portion including an outlet hole from which the processing gas is provided from the gas injector during the semiconductor processing, the outlet hole connected to the inlet hole; and
a collar disposed between the inlet portion and the outlet portion, the collar having a larger diameter than the inlet portion and the outlet portion, the conformal channel extending into the collar.

2. The gas injector of claim 1, wherein:
the conformal channel has a plurality of channel sections each of which extends through the inlet portion and terminates at inlet channel ends before reaching the inlet face.

3. The gas injector of claim 2, wherein:
each channel section also terminates at collar channel ends before reaching the outlet portion.

4. The gas injector of claim 3, wherein:
alternating adjacent pairs of channel sections are connected via the inlet channel ends such that each inlet channel end is separated from an adjacent inlet channel end, and
at least some of adjacent pairs of channel sections not connected via the inlet channel ends arc connected via the collar channel ends.

5. The gas injector of claim 4, wherein:
the collar further comprises a sidewall having ports connected with at least one of the adjacent pairs of channel sections not connected via the inlet channel ends.

6. The gas injector of claim 4, wherein:
the conformal channel is a single channel that extends around substantially an entirety of the inlet hole.

7. The gas injector of claim 4, wherein:
at least one of the inlet channel ends or the collar channel ends of each channel section have an arcuate shape.

8. The gas injector of claim 7, wherein:
the inlet hole comprises a single inlet central bore and a plurality of secondary inlet holes surrounding the inlet central bore, the secondary inlet holes are equidistant from a center of the inlet central bore, each secondary inlet hole is equiangular from each adjacent secondary inlet hole,
the outlet hole comprises a single outlet central bore connected with the inlet central bore and a plurality of secondary outlet holes connected With the secondary inlet holes, the secondary outlet holes are disposed on a sidewall of the outlet portion, and
an arc of one of each inlet channel end or each collar channel end is centered angularly around a different secondary inlet hole.

9. The gas injector of claim 8, wherein:
an arc of at least another of each inlet channel end or each collar channel end is centered angularly between adjacent secondary inlet holes.

10. The gas injector of claim 8, wherein:
each channel section has a diameter smaller than a diameter of each secondary inlet hole.

11. The gas injector of claim 1, further comprising:
a connector integrally formed with the sidewall of the inlet portion, the connector sized to be connected to a gas manifold configured to supply the gas to the gas injector, the gas injector formed from a ceramic material.

12. The gas injector of claim 1, wherein:
the conformal channel is disposed such that at least one dimension of material of the gas injector surrounding the conformal channel is limited to less than about 6 mm.

13. The gas injector of claim 1, wherein:
a depth of damage of the gas injector is less than about 1 micron.

14. A method of fabricating a ceramic gas injector, the method comprising:
printing, using additive manufacturing equipment, a green part corresponding to the gas injector, the green part comprising a ceramic powder and binder, the green part comprising:
an inlet portion comprising a central bore and a conformal channel disposed in a sidewall, the conformal channel terminating before reaching a top face; and
a collar disposed between the inlet portion and an outlet portion, the conformal channel extending into the collar and terminating before extending into the outlet portion, the conformal channel disposed such that at least one dimension of material of the gas injector surrounding the conformal channel is limited to less than about 6 mm:
debinding the green part to remove the binder; and
sintering the green part after the debinding to form the gas injector, the gas injector having a depth of damage less than about 1 micron.

15. The method of claim 14, wherein printing the green part further comprises:
printing the conformal channel to have a plurality of channel sections each of which extends through the inlet portion and terminates at inlet channel ends before reaching the top face, alternating adjacent pairs of channel sections being connected via the inlet channel ends such that each inlet channel end is separated from an adjacent inlet channel end, and all but one adjacent pair of channel sections not connected via the inlet channel ends being connected via the collar channel ends, and
printing the collar to have ports in a sidewall, the ports connected with the one adjacent pair of channel sections not connected via the inlet channel ends.

16. The method of claim 15, wherein:
the central bore is encircled by secondary inlet holes, and
printing the green part further comprises printing the inlet channel ends and the collar channel ends such that an arc of one of each inlet channel end or each collar channel end is centered angularly around a different one of the secondary inlet holes and an arc of at least another of each inlet channel end or each collar channel end is centered angularly between adjacent ones of the secondary inlet holes.

17. A semiconductor processing system comprising:
a gas manifold configured to supply gasses used during semiconductor processing;
a gas injector comprising:
an inlet portion coupled with the gas manifold and to which the gasses are to be introduced via an inlet hole on an inlet face of the inlet portion, the inlet portion comprising a conformal channel disposed between the inlet hole and a sidewall of the inlet portion, the inlet hole comprising a single inlet central bore and a plurality of secondary inlet holes surrounding the inlet central bore, the secondary inlet holes equidistant from a center of the inlet central bore, each secondary inlet hole equiangular from each adjacent secondary inlet hole;
an outlet portion from which the gasses are provided from the gas injector via an outlet hole connected to the inlet hole, the outlet hole comprising a single outlet central bore connected with the inlet central bore and a plurality of secondary outlet holes connected with the secondary inlet holes, the secondary outlet holes disposed on a sidewall of the outlet portion; and
a collar disposed between the inlet portion and the outlet portion, the collar having a larger diameter than the inlet portion and the outlet portion, the conformal channel extending into the collar; and
a processing chamber within which a semiconductor wafer is disposed, the gas injector coupled to the processing chamber such that the gasses are provided into the processing chamber from the outlet portion.

18. The system of claim 17, wherein:
the conformal channel has a plurality of channel sections each of which extends through the inlet portion, terminates at inlet channel ends before reaching the inlet face, and also terminates at collar channel ends before reaching the outlet portion.

19. The system of claim 18, wherein:
alternating adjacent pairs of channel sections are connected via the inlet channel ends such that each inlet channel end is separated from an adjacent inlet channel end,
at least some of adjacent pairs of channel sections not connected via the inlet channel ends are connected via the collar channel ends, and
the collar further comprises a sidewall having ports connected with at least one of the adjacent pairs of channel sections not connected via the inlet channel ends.

20. The system of claim 17, further comprising:
a connector integrally formed with the sidewall of the inlet portion, the connector sized to be connected to the gas manifold.
